(19) United States
(12) Patent Application Publication
(10) Pub. No.: US 2019/0237325 A1
(43) Pub. Date: Aug. 1, 2019

(54) CARBON FILM GAPFILL FOR PATTERNING APPLICATION

(71) Applicant: Applied Materials, Inc., Santa Clara, CA (US)

(72) Inventors: Fei WANG, Fremont, CA (US); Miaojun WANG, San Jose, CA (US); Shishi JIANG, Santa Clara, CA (US); Pramit MANNA, Sunnyvale, CA (US); Abhijit Basu MALLICK, Fremont, CA (US); Robert Jan VISSER, Menlo Park, CA (US)

(21) Appl. No.: 15/880,702

(22) Filed: Jan. 26, 2018

(51) Int. Cl. H01L 21/027; H01L 21/033; H01L 21/311

(52) U.S. Cl. CPC H01L 21/0273; H01L 21/0332; H01L 21/31116; H01L 21/0335; H01L 21/31138

(57) ABSTRACT

Embodiments described herein relate to methods for forming patterns of semiconductor devices utilizing parylene gapfill layers deposited using a thermal chemical vapor deposition (CVD) process. In one embodiment the patterns of semiconductor devices are formed by forming amorphous carbon (a-C) mandrels on first layers, depositing amorphous silicon (a-Si) layers over the a-C mandrels and the first layers, etching the a-Si spacer layers to expose top surfaces of the a-C mandrels and to expose the first layers, depositing parylene gapfill layers using the CVD process, removing portions of the parylene gapfill layers until the top surfaces are exposed; and removing the a-Si spacer layers to expose the first layers and form patterns of semiconductor devices having a-C mandrels and parylene mandrels.

### BACKGROUND

### Field

Embodiments of the present disclosure generally relate to methods for forming patterns of semiconductor devices. More particularly, embodiments of the present disclosure relate to pattern forming methods utilizing a parylene gapfill layer deposited using a thermal CVD process.

### Description of the Related Art

Semiconductor device processing is used to create integrated circuits that are present in electrical devices.

Conventionally, in the fabrication of integrated circuits, photo lithography scanners using 193 nanometer (nm) wavelength lasers and numerical apertures of 1.35 have reached fundamental printing limits of 40 nm to 45 nm. However, there are demands and device trends for smaller feature sizes not obtainable by photo lithography. Multi-color patterning processes are used to form lines, vias, trenches, contacts, devices, gates and other features on substrates Multi-color patterning processes form smaller features not obtainable by photo lithography.

In order to form features having smaller dimensions, such as sub-nano dimensions, gapfill layers are necessary to fill gaps formed between spacer layers disposed on mandrels formed on substrates. The spacer layers and/or mandrels are removed to form positive tones (lines) or negative tones (trenches) with small dimensions. Therefore, the gapfill layers must survive etching processes that remove the spacer layers and/or mandrels and must be thermally stable to withstand processing.

Accordingly, what is needed in the art are improved methods for forming patterns of semiconductor devices with gapfill layers.

### SUMMARY

In one embodiment, a method for forming a pattern of a semiconductor device is provided. The method includes forming a plurality of amorphous carbon (a-C) mandrels on a first layer. An amorphous silicon (a-Si) spacer layer is deposited over the plurality of a-C mandrels and the first layer. The a-Si spacer layer is etched to expose top surfaces of the plurality of a-C mandrels and to expose the first layer. A parylene gapfill layer is deposited using a thermal chemical vapor deposition (CVD) process. Portions of the parylene gapfill layer are removed until the top surfaces are exposed and the a-Si spacer layer is removed to expose the first layer.

In another embodiment, a method for forming a pattern of a semiconductor device is provided. The method includes forming a plurality of mandrels on a substrate having gaps between respective facing portions with a first material and a second material alternately disposed in the gaps. Portions of the first material are removed and a first parylene gapfill layer is deposited using a thermal CVD process. Portions of the first parylene gapfill layer are removed until top surfaces of the plurality of mandrels are exposed. Portions of the second material are removed and a second parylene gapfill layer is deposited using the thermal CVD process. Portions of the second parylene gapfill layer are removed until the top surfaces of the plurality of mandrels are exposed

In another embodiment, a method for forming a pattern of a semiconductor device is provided. The method includes forming a plurality of amorphous silicon (a-Si) mandrels on a first layer. A silicon nitride (SiN) spacer layer is deposited over the plurality of a-Si mandrels and the first layer. The SiN spacer layer is etched to expose top surfaces of the plurality of a-Si mandrels and to expose the first layer. A parylene gapfill layer is deposited using a thermal CVD process. Portions of the parylene gapfill layer are removed until the top surfaces are exposed and the plurality of a-Si mandrels is removed to expose the first layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic, cross-sectional view of a thermal chemical vapor deposition (CVD) chamber that may be used for deposition a parylene gapfill layer according to embodiments.

FIG. 2 is a flow chart illustrating operations of a method for forming a pattern of a semiconductor device according to an embodiment.

FIGS. 3A-3H are schematic, cross-sectional views of a pattern of a semiconductor device during the method for forming a pattern of a semiconductor device according to an embodiment.

FIG. 4 is a flow chart illustrating operations of a method for forming a pattern of a semiconductor device according to another embodiment.

FIGS. 5A-5G are schematic, cross-sectional views of a pattern of a semiconductor device during the method for forming a pattern of a semiconductor device according to another embodiment.

FIG. 6 is a flow chart illustrating operations of a method for forming a pattern of a semiconductor device according to another embodiment.

FIG. 7A-7C is a schematic, cross-sectional view of a pattern of a semiconductor device during the method for forming a pattern of a semiconductor device according to another embodiment

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to methods for forming patterns of semiconductor devices utilizing parylene gapfill layers deposited using a thermal chemical vapor deposition (CVD) process. In one embodiment the patterns of semiconductor devices are formed by forming amorphous carbon (a-C) mandrels on first layers, depositing amorphous silicon (a-Si) layers over the a-C mandrels and the first layers, etching the a-Si spacer layers to expose top surfaces of the a-C mandrels and to expose the first layers, depositing parylene gapfill layers using the CVD process, removing portions of the parylene gapfill layers until the top surfaces are exposed; and removing the a-Si spacer layers to expose the first layers and form patterns of semiconductor devices having a-C mandrels and parylene mandrels.

As used herein, the term “parylene” is the generic name for thermoplastic polymers based on p-xylylene (CH₂C₆H₄CH₂) or derivatives of the parylene monomers, polymers, or copolymers. The nonsubstituted p-xylylene polymers have the formula:

—(CH₂—C₆H₄—CH₂—)ₙ—

wherein n is sufficient to provide high strength. The polymer grows by addition of monomers on both ends, and the end groups, which are not easily identified, have no influence on properties. The term “parylene” is also intended to cover chlorinated or fluorinated forms of the parylene polymers produced by halogenating the monomers or the polymers.

Parylene can be deposited with a comonomer. The comonomer has at least a carbon-carbon double bond from a vinyl group or an acrylic group. Parylene may contain F, N, O, Si atoms as well. The parylene monomer is mixed with the comonomer and is flowed into the process chamber. The amount of the comonomer blended with a gaseous flow of p-xylylene monomer and carrier gas may range from about 5% by Wt. to about 25% by Wt. of a total mixture of monomers, but preferably the amount of comonomer will range from about 5% by Wt. to about 15% by Wt., with a typical amount of copolymerizable monomer added usually comprising at least 10% by Wt. of the monomer mixture total.

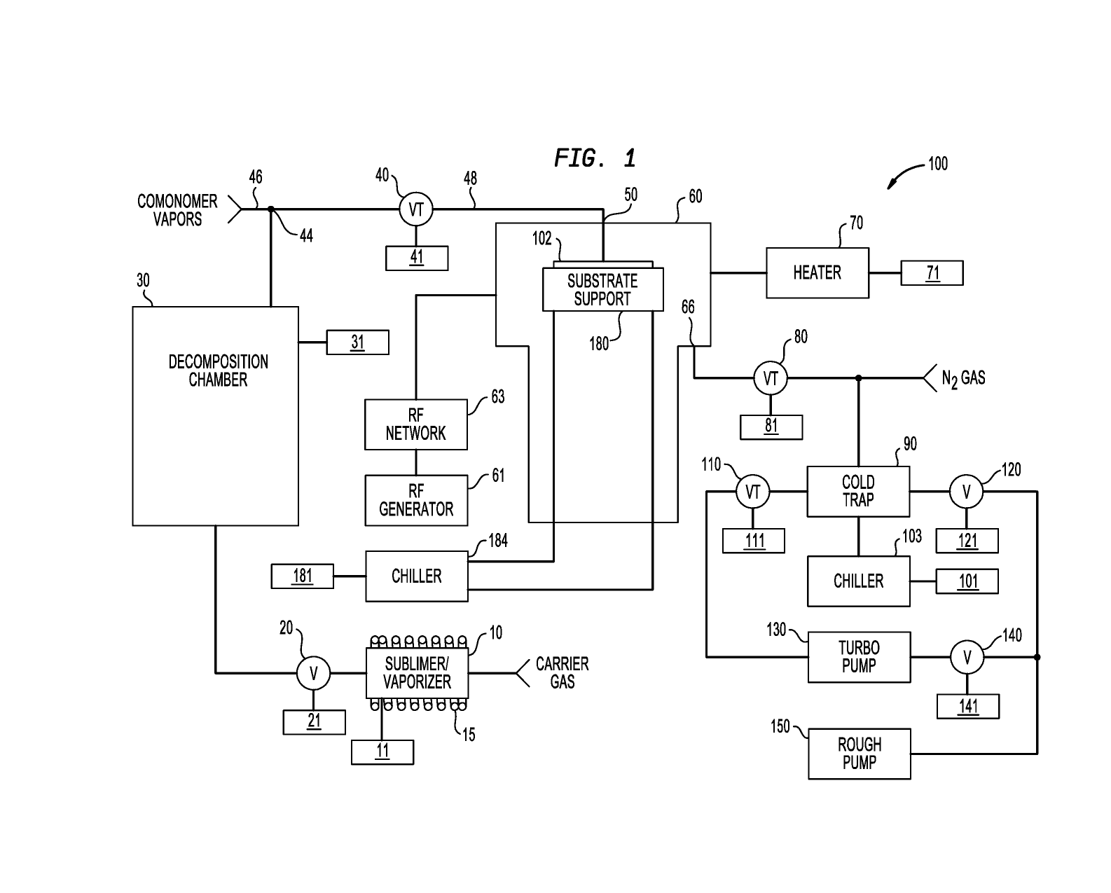

FIG. 1 is a schematic cross-sectional view of a thermal chemical vapor deposition (CVD) chamber 100 that may be used for deposition a parylene gapfill layer according to embodiments described herein. It is to be understood that the chamber described below is an exemplary chamber and other chambers, including chambers from other manufacturers, may be used with or modified to accomplish aspects of the present disclosure.

The thermal CVD chamber 100 includes, a sublimer or vaporizer 10 is provided to heat and vaporize or sublime a dimer. The vaporizer 10 may have a heating coil 15. The heating coil 15 is wrapped around the vaporizer 10 and is connected to an external electrical power source 11. The vaporizer 10 is maintained at a temperature of about 70° C. to about 200° C. and pressure of about 1 millitorr (mTorr) to about 1 Torr. The vaporized dimer, such as Parylene-N, or mixture of vaporized dimer and a carrier gas, then passes from vaporizer 10 through a gate valve 20 to a pyrolysis or decomposition chamber 30 where the vaporized dimer is at least partially decomposed or pyrolized. Nitrogen gas (N₂) may be used as carrier gas with a rate of about 0.5 standard cubic centimeters per minute (sccm) to about 1000 sccm, preferably about 0.5 sccm to about 100 sccm into the vaporizer 10. The gate valve 20 is connected to a valve controller 21.

The decomposition chamber 30 comprises a ceramic furnace (not shown) having heater wires (not shown) to heat a metal cylinder (not shown) of the decomposition chamber 30. The heater wires of the ceramic furnace are connected to an external power supply (not shown) and a temperature controller 31 to maintain temperature. The decomposition chamber 30 is maintained at a temperature of about 550° C. to about 700° C. and pressure of about 1 mTorr to about 1 Torr.

The thermal CVD chamber 100 further includes valve controllers 41, 81, 111, 121, 141, and chiller controllers 101 and 181. The decomposed or pyrolized dimer passes out of the decomposition chamber 30 to a tee 44 where it is blended with a comonomer, in vaporized form, from a conduit 46. The vaporized dimer and the comonomer then flow through a second gate valve 40 to a conduit 48 connected to an entrance port 50 to a deposition chamber 60 at a rate of about 0.5 sccm to about 100 sccm where a parylene layer is deposited, which is preferably temperature controlled by a support member 180 that is connected to a chiller 184. The support member 180 is configured to support a substrate 102. The deposition chamber 60 is maintained at a temperature of about −10° C. to about 150° C. and pressure of about 1 mTorr to about 1 Torr.

The walls of deposition chamber 60 are maintained by a heater 70, under the control of a heater controller 71. The remaining gas/vapor mixture then passes from the deposition chamber 60 through a throttle valve 80 from an exit port 66, under the control of valve controller 81, and then passes through a cold trap 90 connected to a chiller 103. The remaining gases then pass through a gate valve 120, controlled by valve controller 121, to a rough pump 150. The cold trap 90 is also connected through a gate valve 110 to a turbo pump 130 and then through an isolation valve 140 to the rough pump 150. Furthermore, the thermal CVD chamber 100 may include an RF generator 61 which is coupled to the deposition chamber 60 through an RF network 63 to permit generation of a plasma within the deposition chamber 60.

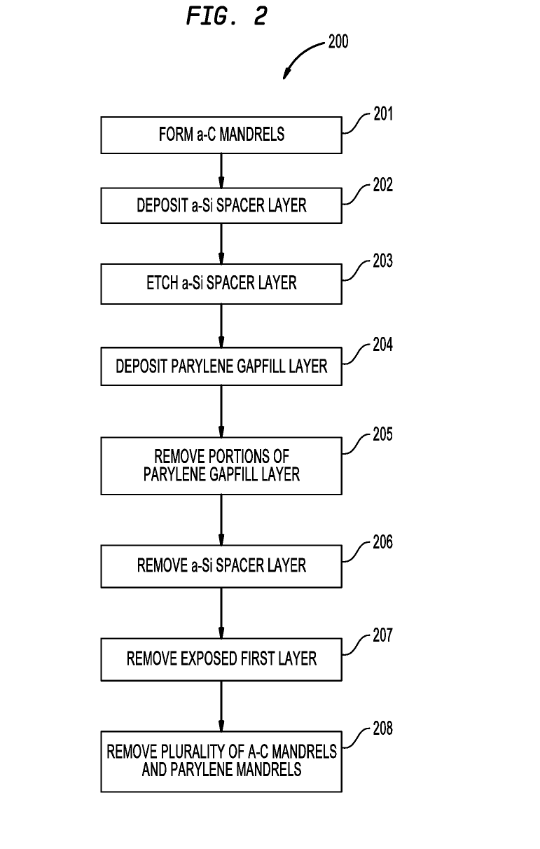

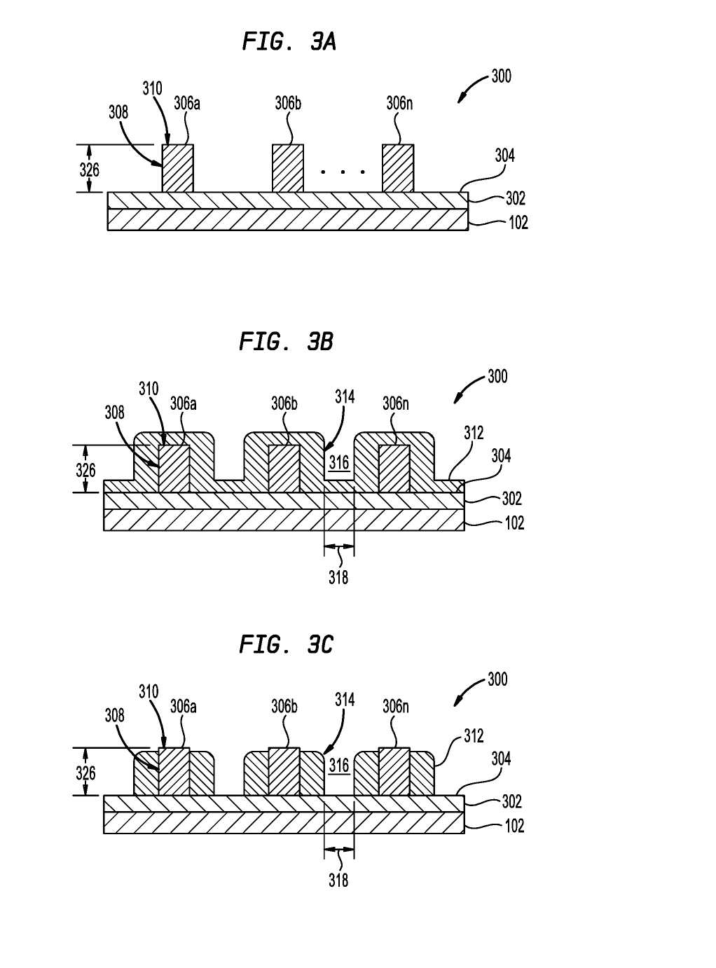

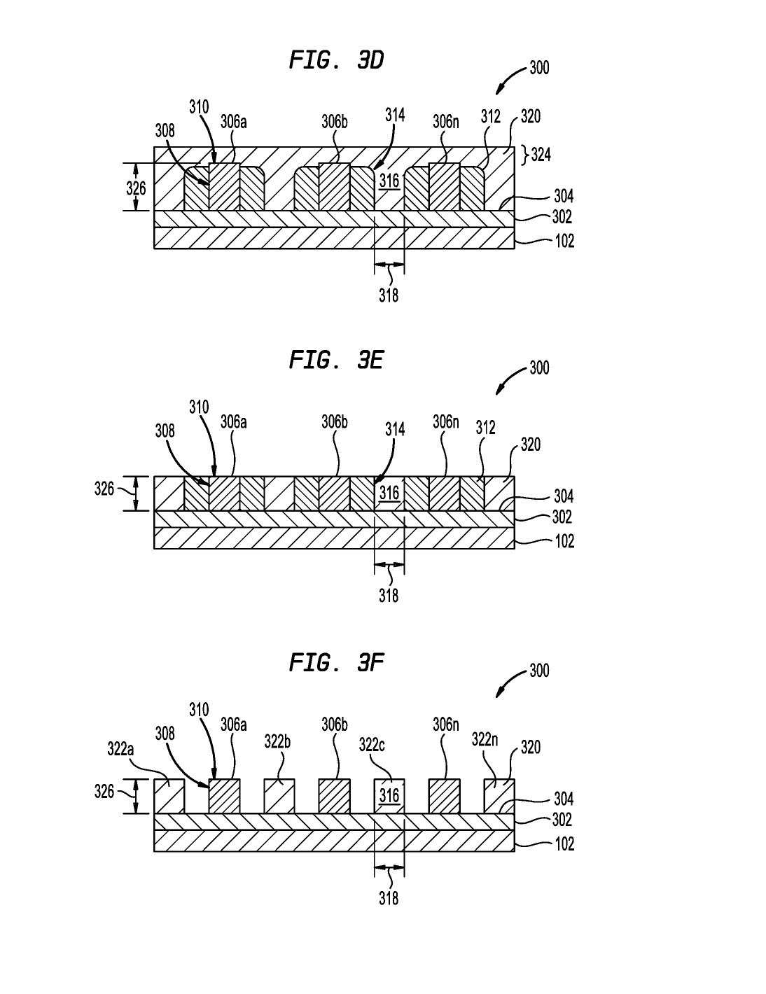

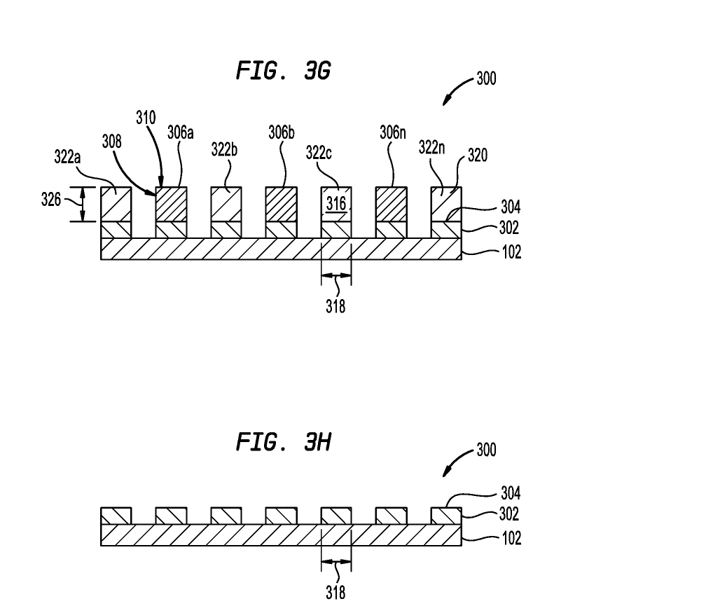

FIG. 2 is a flow diagram illustrating operations of a method 200 for forming a pattern of a semiconductor device 300 as shown in FIGS. 3A-3H. At operation 201, mandrels 306a, 306b, . . . 306n are formed on a first layer 302. The first layer 302 may be the substrate 102 or a layer disposed on a substrate 102. The first layer 302 has a surface 304. The first layer 302 may contain a silicon (Si) containing material, a silicon dioxide (SiO₂) containing material, or a silicon nitride (SiN) containing material. The mandrels 306a, 306b, . . . 306n are amorphous carbon (a-C) mandrels. In another embodiment, the mandrels 306a, 306b, . . . 306n are amorphous silicon (a-Si) mandrels. As shown in FIG. 3A, the plurality of a-C mandrels 306 have a height 326 of about 1 nanometers (nm) to about 100 nm from top surfaces 310 of the plurality of a-C mandrels 306 to the surface 304 of the first layer 302. The plurality of a-C mandrels 306 may contain parylene.

At operation 202, a spacer layer 312 is deposited over the plurality of a-C mandrels 306 and the first layer 302. The spacer layer 312 is amorphous silicon (a-Si). In another embodiment, the spacer layer 312 is silicon nitride (SiN). The a-Si spacer layer 312 may contain a nitrogen (N) containing material or an oxygen (O) containing material. The a-Si spacer layer 312 may be conformally deposited on the top surfaces 310 and sidewalls 308 of the plurality of a-C mandrels 306 to form gaps 316 between respective facing portions 314 of the a-Si spacer layer 312 on the sidewalls 308 of the plurality of a-C mandrels 306. As shown in FIG. 3B, the gaps 316 have a width 318 of about 1 nm to about 10 nm between the respective facing portions 314. The gaps 316 have an aspect ratio that is greater than 5:1. At operation 203, the a-Si spacer layer 312 is removed to expose top surfaces 310 of the plurality of a-C mandrels 306 and to expose the first layer 302. In one embodiment, the removal process is an etching process.

At operation 204, a parylene gapfill layer 320 is deposited using a thermal chemical vapor deposition (CVD) process. The parylene gapfill layer 320 has a thermal stability that is substantially improved as compared to parylene that is spin on coated (SOC). The parylene gapfill layer 320 is thermally stable up to 450° C. Parylene that is SOC is thermally stable up to 315° C. Furthermore, an etch selectivity between the parylene gapfill layer 320 and a-Si is greater than 10:1 as compared to 6:1 for parylene that is SOC. The etch selectivity between the parylene gapfill layer 320 and SiO is greater than parylene that is SOC The etch selectivity between the parylene gapfill layer 320 and SiN is greater than parylene that is SOC.

At operation 205, portions 324 of the parylene gapfill layer 320 are removed until the top surfaces 310 of the plurality of a-C mandrels 306 are exposed. Removing portions 324 of the parylene gapfill layer 320 may include redepositing the parylene gapfill layer 320 at other locations or oxygen plasma etching to planarize the parylene gapfill layer 320. At operation 206, the a-Si spacer layer 312 is removed to expose the first layer 302 and to form parylene mandrels 322a, 322b, 322c, . . . 322n (collectively referred to as the “plurality of parylene mandrels 322”) formed in the gaps 316. Removing the a-Si spacer layer 312 may include fluorine containing plasma etching. At operation 207, the plurality of a-C mandrels 306 and parylene mandrels 322 are used as a mask and the exposed first layer 302 is removed to pattern the first layer 302. Removing the exposed first layer 302 may include fluorine containing plasma etching. At operation 208, the plurality of a-C mandrels 306 and the parylene mandrels 322 are removed to form the pattern of a semiconductor device 300. Removing the plurality of a-C mandrels 306 and the parylene mandrels 322 may include plasma ashing.

At the conclusion of method 200, further processing may be performed thereafter to the pattern of a semiconductor device 300.

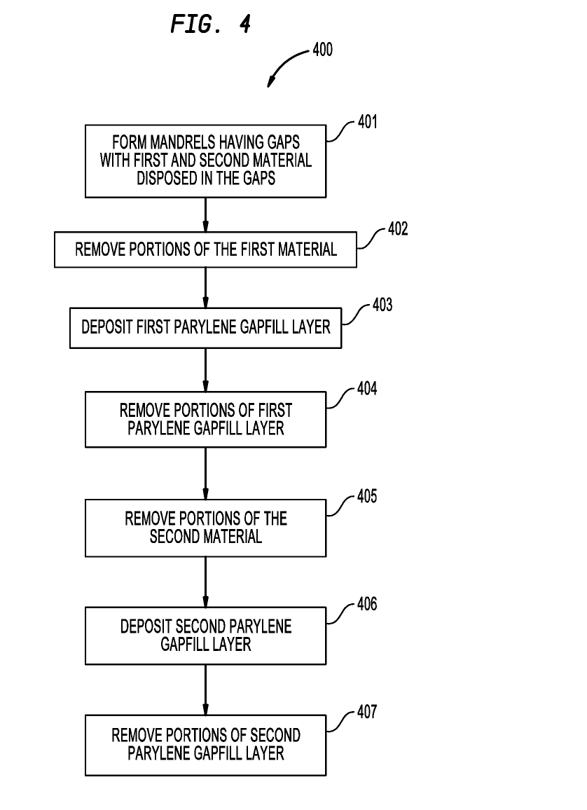

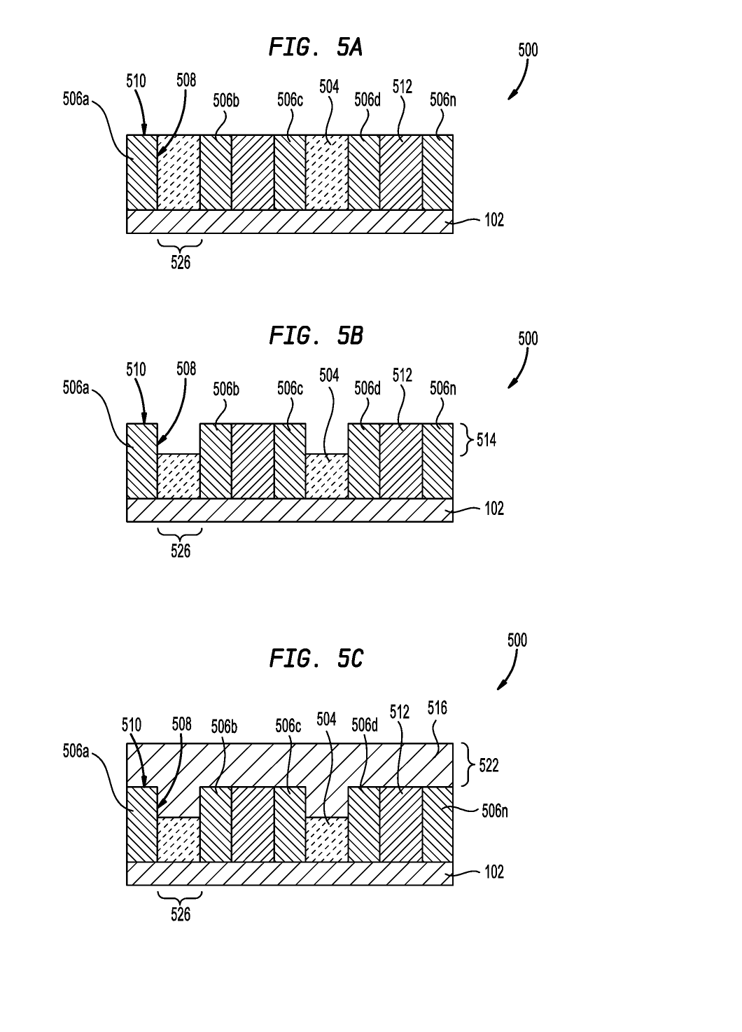

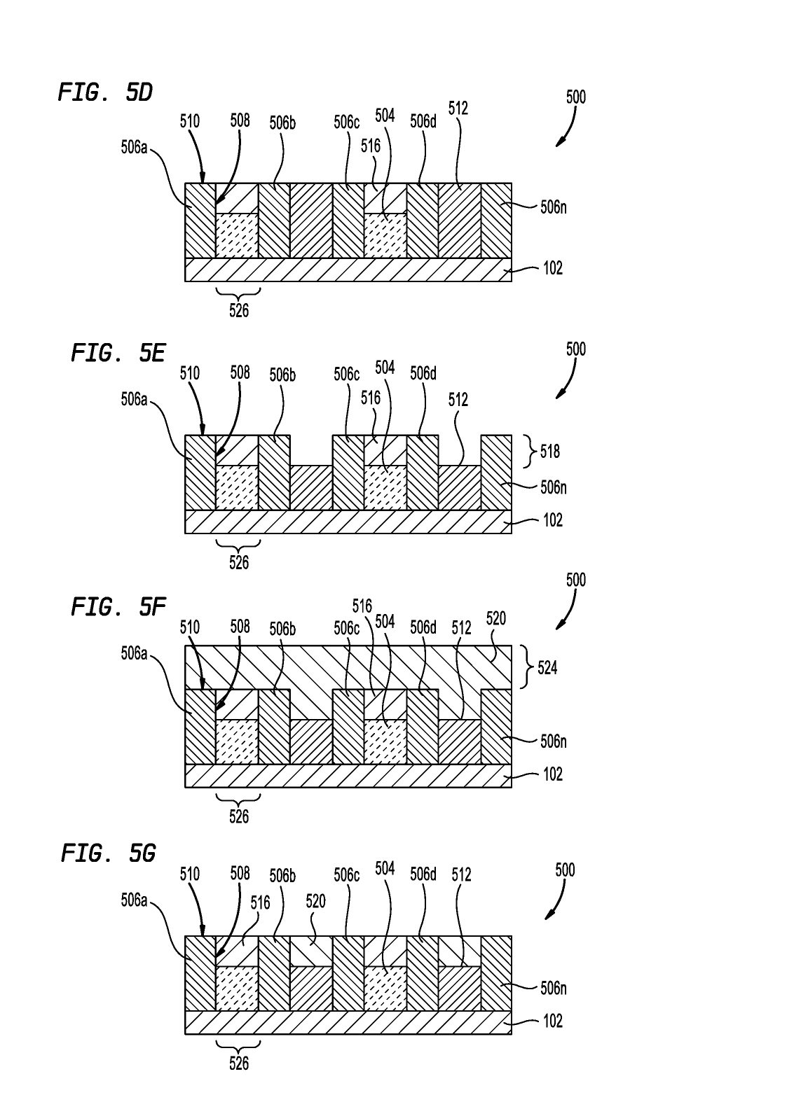

FIG. 4 is a flow diagram illustrating operations of a method 400 for forming a pattern of a semiconductor device 500 as shown in FIGS. 5A-5G. At operation 401, mandrels 506a, 506b, 506c, 506d, . . . 506n (collectively referred to as “the plurality of mandrels 506”) are formed on a substrate 102. As shown in FIG. 5A, a first material 504 and a second material 512 are alternately disposed in gaps 526 between respective facing portions 508 of the plurality of mandrels 506. The gaps 526 have an aspect ratio that is greater than 5:1. The plurality of mandrels 506 may include dielectric materials such as amorphous carbon (C), silicon (Si), silicon oxide (SiO), silicon nitride (SiN), and silicon oxycarbide (SiOC). The first material 504 and second material 512 may include metals, such as copper (Cu), platinum (Pt), ruthenium (Ru), cobalt (Co), nickel (Ni), tungsten (W), palladium (Pd), or metal oxides. At operation 402, portions 514 of the first material 504 are removed. Removing the portions 514 of the first material 504 may include selective etching. For example, the portions 514 of the first material 504 are removed utilizing a etch selectivity of the first material 504 over the second material 512 and the materials of plurality of mandrels 506.

At operation 403, a first parylene gapfill layer 516 is deposited using the thermal chemical vapor deposition (CVD) process. At operation 404, portions 522 of the first parylene gapfill layer 516 are removed until top surfaces 510 the plurality of mandrels 506 are exposed. Removing portions 522 of the first parylene gapfill layer 516 includes redepositing the first parylene gapfill layer 516 at other locations or oxygen plasma etching to planarize the first parylene gapfill layer 516.

At operation 405, portions 518 of the second material 512 are removed. Removing the portions 518 of the second material 512 may include selectively etching. For example, the portions 518 of the second material 512 are removed utilizing a high etch selectivity of the second material 512 over first parylene gapfill layer 516 and the materials of plurality of mandrels 506. At operation 406, a second parylene gapfill layer 520 is deposited using the thermal CVD process. At operation 407, portions 524 of the second parylene gapfill layer 520 are removed until the top surfaces 510 the plurality of mandrels 506 are exposed. Removing portions 524 of the second parylene gapfill layer 520 includes redepositing the second parylene gapfill layer 520 at other locations or oxygen plasma etching to planarize the second parylene gapfill layer 520.

At the conclusion of method 400, further processing such as may be performed thereafter to the pattern of a semiconductor device 500.

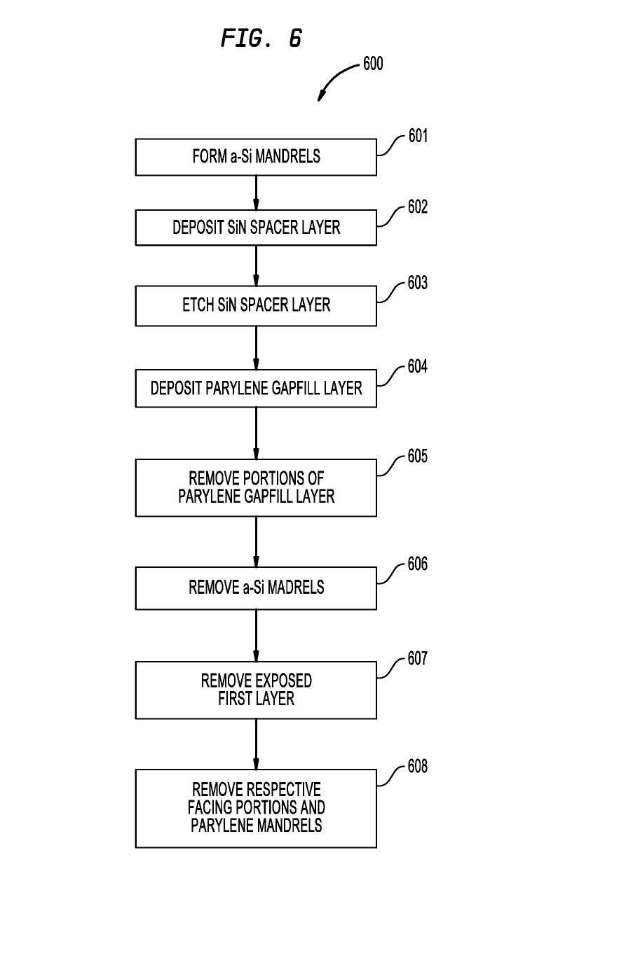

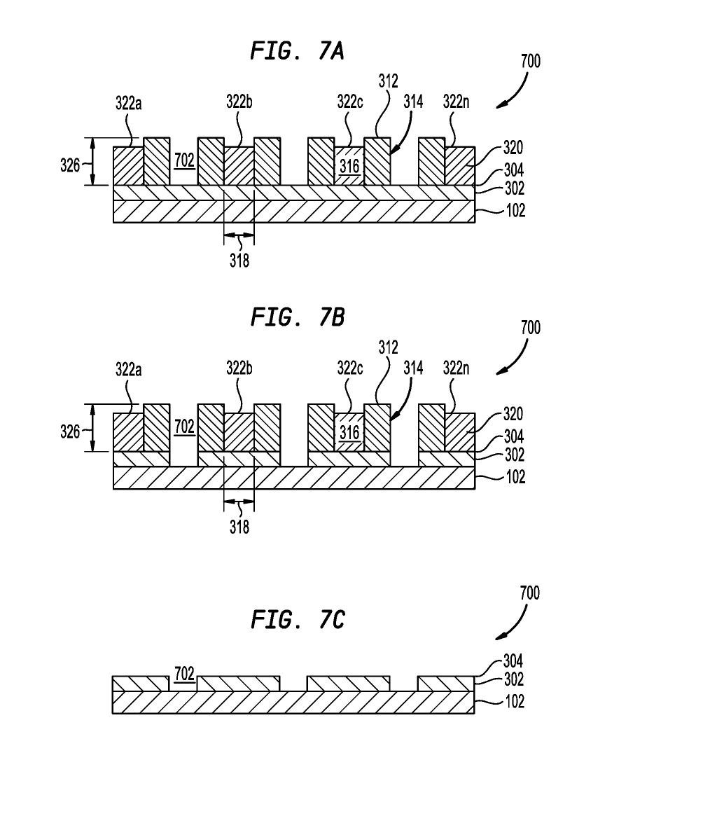

FIG. 6 is a flow diagram illustrating operations of a method 600 for forming a pattern of a semiconductor device 700 as shown in FIGS. 7A-7C. Operations 601-605 of the method 600 for forming the pattern of a semiconductor device 700 are illustrated in FIGS. 3A-3E.

At operation 601, a-Si mandrels 306a, 306b, . . . 306n are formed on a first layer 302. At operation 602, a silicon nitride (SiN) spacer layer 312 is deposited over the plurality of a-Si mandrels 306 and the first layer 302. As shown in FIG. 3B, the SiN spacer layer 312 may be conformally deposited on the top surfaces 310 and sidewalls 308 of the plurality of a-Si mandrels 306 to form gaps 316 between respective facing portions 314 of the SiN spacer layer 312 on the sidewalls 308 of the plurality of a-Si mandrels 306. The gaps 316 have an aspect ratio that is greater than 5:1. At operation 603, the SiN spacer layer 312 is etched to expose top surfaces 310 of the plurality of a-Si mandrels 306 and to expose the first layer 302. At operation 604, a parylene gapfill layer 320 is deposited using the thermal chemical vapor deposition (CVD) process. At operation 605, portions 324 of the parylene gapfill layer 320 are removed until the top surfaces 310 of the plurality of a-Si mandrels 306 are exposed

As shown in FIG. 7A, at operation 606, the plurality of a-Si mandrels 306 are removed to expose the first layer 302 and to form gaps 702 where the first layer 302 is exposed. A plurality of parylene mandrels 322 are formed in the gaps 316. Removing the plurality of a-Si mandrels 306 may include fluorine containing plasma etching. At operation 607, the SiN spacer layer 312 and the plurality of parylene mandrels 322 are used as a mask and the exposed first layer 302 is removed to pattern the first layer 302. At operation 608, the respective facing portions 314 and the parylene mandrels 322 are removed to form the pattern of a semiconductor device 700. Removing the respective facing portions 314 and the parylene mandrels 322 may include plasma ashing.

At the conclusion of method 600, further processing may be performed thereafter to the pattern of a semiconductor device 700.

In summation, methods for forming patterns of semiconductor devices utilizing parylene gapfill layers deposited using a thermal chemical vapor deposition (CVD) process are described herein. The utilization of parylene gapfill layers deposited using the thermal CVD process provides for patterns with sub-nano dimension features. The thermal stability of thermal CVD gapfill parylene and the etch selectivity of thermal CVD gapfill parylene to Si, SiN, and SiO provide resistance to etching processes that remove the spacer layers and/or mandrels.

While the foregoing is directed to examples of the present disclosure, other and further examples of the disclosure may be devised without departing from the basic scope thereof, and the scope thereof is determined by the claims that follow.

What is claimed is:

1. A method for forming a pattern of a semiconductor device, comprising:
forming a plurality of amorphous carbon (a-C) mandrels on a first layer;
depositing an amorphous silicon (a-Si) spacer layer over the plurality of a-C mandrels and the first layer;
etching the a-Si spacer layer to expose top surfaces of the plurality of a-C mandrels and to expose the first layer;
depositing a parylene gapfill layer using a thermal chemical vapor deposition (CVD) process;
removing portions of the parylene gapfill layer until the top surfaces are exposed; and
removing the a-Si spacer layer to expose the first layer.

2. The method of claim 1, wherein the parylene gapfill layer deposited by the thermal CVD process is thermally stable up to 450° C.

3. The method of claim 1, wherein an etch selectivity between the parylene gapfill layer and the a-Si spacer layer is greater than 10:1.

4. The method of claim 1, wherein the a-Si spacer layer comprises a nitrogen (N) containing material or an oxygen (O) containing material.

5. The method of claim 1, wherein the plurality of a-C mandrels comprises parylene.

6. The method of claim 5, wherein the removing portions of the parylene gapfill layer comprises oxygen plasma etching.

7. The method of claim 6, further comprising redepositing the removed portions of the parylene gapfill layer at other locations.

8. The method of claim 1, wherein the a-Si spacer layer is conformally deposited on the top surfaces and sidewalls of the plurality of a-C mandrels to form gaps between respective facing portions of the a-Si spacer layer on the sidewalls of the plurality of a-C mandrels.

9. The method of claim 8, wherein the gaps have an aspect ratio that is greater than 5:1.

10. A method for forming a pattern of a semiconductor device, comprising:
forming a plurality of mandrels on a substrate having gaps between respective facing portions with a first material and a second material alternately disposed in the gaps;
removing portions of the first material;
depositing a first parylene gapfill layer using a thermal chemical vapor deposition (CVD) process;
removing portions of the first parylene gapfill layer until top surfaces of the plurality of mandrels are exposed;
removing portions of the second material;
depositing a second parylene gapfill layer using the thermal CVD process; and
removing portions of the second parylene gapfill layer until the top surfaces of the plurality of mandrels are exposed.

11. The method of claim 10, wherein the gaps have an aspect ratio that is greater than 5:1

12. The method of claim 10, wherein the first parylene gapfill layer and second parylene gapfill layer deposited by the thermal CVD process are thermally stable up to 450° C.

13. The method of claim 10, wherein the first material and the second material comprise metals or metal oxides.

14. The method of claim 10, wherein the removing portions of the first parylene gapfill layer and the removing portions of the second parylene gapfill layer comprise oxygen plasma etching.

15. A method for forming a pattern of a semiconductor device, comprising:
forming a plurality of amorphous silicon (a-Si) mandrels on a first layer;
depositing a silicon nitride (SiN) spacer layer over the plurality of a-Si mandrels and the first layer;
etching the SiN spacer layer to expose top surfaces of the plurality of a-Si mandrels and to expose the first layer;
depositing a parylene gapfill layer using a thermal chemical vapor deposition (CVD) process;
removing portions of the parylene gapfill layer until the top surfaces are exposed; and
removing the plurality of a-Si mandrels to expose the first layer.

16. The method of claim 15, wherein the parylene gapfill layer deposited by the thermal CVD process is thermally stable up to 450° C.

17. The method of claim 15, wherein an etch selectivity between the parylene gapfill layer and the plurality of a-Si mandrels is greater than 10:1.

18. The method of claim 15, wherein the removing portions of the parylene gapfill layer comprises oxygen plasma etching.

19. The method of claim 15, wherein the SiN spacer layer is conformally deposited on the top surfaces and sidewalls of the plurality of a-Si mandrels to form gaps between respective facing portions of the SiN spacer layer on the sidewalls of the plurality of a-Si mandrels.

20. The method of claim 19, wherein the gaps have an aspect ratio that is greater than 5:1.
